(19) United States
(12) Patent Application Publication
(10) Pub. No.: US 2012/0048356 A1
(43) Pub. Date: Mar. 1, 2012

(54) DOPING PASTE, SOLAR CELL, AND METHOD OF MANUFACTURING THE SAME

(75) Inventors: Sang-Soo JEE, Hwaseong-si (KR); Eun-Sung LEE, Seoul (KR); Se-Yun KIM, Seoul (KR); Vladimir URAZAEV, Suwon-si (KR); Jung Yun WON, Hwaseong-si (KR); Mi-Jeong SONG, Suwon-si (KR)

(73) Assignee: SAMSUNG ELECTRONICS CO., LTD., Suwon-si (KR)

(21) Appl. No.: 13/037,071

(22) Filed: Feb. 28, 2011

(30) Foreign Application Priority Data
Aug. 24, 2010 (KR) 10-2010-0082070

(51) Int. Cl. H01L 31/02; H01B 1/04; H01B 1/02; H01L 31/18

(52) U.S. Cl. 136/252; 438/57; 252/500; 252/519.14; 257/E31.11

(57) ABSTRACT

A doping paste includes an inorganic particle including a phosphorus-containing silicon compound and an organic vehicle, wherein a concentration of phosphorus at an interior portion of the inorganic particle is greater than a concentration of phosphorous at a surface of the inorganic particle.

### CROSS-REFERENCE TO RELATED APPLICATION

This application claims priority to Korean Patent Application No. 10-2010-0082070, filed on Aug. 24, 2010, and all the benefits accruing therefrom under 35 U.S.C. §119, the content of which in its entirety is herein incorporated by reference.

### BACKGROUND

1. Field

This disclosure relates to a doping paste, a solar cell, and a method of manufacturing the same.

2. Description of the Related Art

A solar cell is a photoelectric conversion device that converts solar energy to electrical energy. Solar cells have attracted increased attention as a potentially unlimited, non-polluting next generation energy source.

A solar cell includes a p-type semiconductor and an n-type semiconductor. If a solar cell absorbs solar energy in a photoactive layer, electron-hole pairs (“EHP”) are produced in the semiconductors, and the produced electrons and holes move to the n-type semiconductor and the p-type semiconductor, respectively, and are collected at electrodes, and thus may be used to provide electrical energy.

The p-type semiconductor and the n-type semiconductor may be formed by various methods, for example by deposition of a p-type dopant and an n-type dopant.

However, deposition can include complicated processes, have high costs, and can have along process time. Accordingly, a printing method using a doping paste including p-type or n-type dopants has been suggested.

### SUMMARY

An aspect of this disclosure provides a doping paste which is capable of reducing costs and simplifying an electronic device manufacturing process.

Another aspect of this disclosure provides an electronic device including an electrode formed using the doping paste.

Yet another aspect of this disclosure provides a solar cell including an emitter layer formed using the doping paste.

Yet another aspect of this disclosure provides a method of manufacturing the solar cell.

An aspect provides a doping paste including: an inorganic particle including a phosphorus-containing silicon compound, and an organic vehicle, wherein a concentration of phosphorus at an interior portion of the inorganic particle is greater than a concentration of phosphorous at a surface of the inorganic particle.

The phosphorus-containing silicon compound may include a phosphosilicate crystal, a phosphosilicate glass, or a combination thereof.

The phosphorus-containing silicon compound may include a phosphosilicate glass represented by the following Chemical Formula 1.

xSiO₂-yP₂O₅-zMO₁ Chemical Formula 1

In Chemical Formula 1, x>0, y>0, z≧0, and M is a metal.

The inorganic particle may include a phosphorus-rich region located at a center of the inorganic particle, and a silicon-rich region located at the surface of the inorganic particle, and wherein the silicon-rich region has a ratio of phosphorus to silicon which is less than a ratio of phosphorous to silicon of than the phosphorus-rich region.

The inorganic particle may have particle size of about 0.5 to about 50 micrometers (μm).

The inorganic particle and the organic vehicle may be present in an amount of about 1 to about 80 weight percent (wt %) and about 20 to about 99 wt %, respectively, based on a total weight of the doping paste.

Another embodiment provides a method of manufacturing a solar cell, including: disposing a doping paste including an inorganic particle and an organic vehicle on a first surface of a semiconductor substrate, wherein the inorganic particle includes a phosphorus-containing silicon compound and an organic vehicle, and wherein a concentration of phosphorus at an interior portion of the inorganic particle is greater than a concentration of phosphorous at a surface of the inorganic particle; and heat-treating the semiconductor substrate to which the doping paste is disposed.

The method may further include preparing the inorganic particle, wherein the preparing of the inorganic particle may include contacting a particle includes the phosphorus-containing silicon compound with water to remove phosphorous from the surface of the inorganic particle, wherein the water is a liquid, a vapor, or a supercritical fluid; and then contacting the particle including the phosphorus-containing silicon compound with water or an organic solvent to clean the particle.

The disposing may include disposing the n-type doping paste on an entire surface or a portion of a surface of the semiconductor substrate by screen printing.

The heat treating of the semiconductor substrate onto which the n-type doping paste is disposed may include heat treating at a first temperature to remove the organic vehicle, and then heat treating at a second temperature, which is higher than the first temperature, to dope the semiconductor substrate with an n-type impurity.

The first temperature may be about 100° C. to about 600° C.

The second temperature may be about 700° C. to about 1100° C.

The method may further include after the heat-treating of the semiconductor substrate, disposing a p-type doping paste, which is different than the n-type doping paste, on a second side of the semiconductor substrate, and then heat-treating the semiconductor substrate.

The n-type doping paste and the p-type doping paste may be disposed on a same side of the semiconductor substrate, and the n-type doping paste and the p-type doping paste may be alternately disposed.

Another embodiment provides an electronic device including an electrode formed using the doping paste.

Yet another embodiment provides a solar cell including a semiconductor substrate, an emitter layer disposed on a side of the semiconductor substrate, and an electrode electrically connected with the emitter layer, wherein the emitter layer includes a heat-treated product of a doping paste which includes an inorganic particle including a phosphorus-containing silicon compound, wherein a concentration of phosphorus at an interior portion of the inorganic particle is greater than a concentration of phosphorous at a surface of the inorganic particle.

The phosphorus-containing silicon compound may include a phosphosilicate glass represented by the above Chemical Formula 1.

The inorganic particle may include a phosphorus-rich region located at a center of the inorganic particle, and a silicon-rich region located at the surface of the inorganic particle, and wherein the silicon-rich region has a ratio of phosphorus to silicon which is less than a ratio of phosphorous to silicon of the phosphorus (P)-rich region.

The emitter layer may be disposed on an entire surface of or on a portion of a surface of the semiconductor substrate.

The doping paste may further include conductive material, and the emitter layer and the electrode may be integratedly formed using the doping paste.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a schematic diagram showing an embodiment of an inorganic particle of a doping paste;

FIG. 2 is a graph of concentration (atoms per cubic centimeter) versus depth (nanometers) showing a secondary ion mass spectrometry (“SIMS”) result showing the content of adsorbed carbon (C) according to the content of phosphorus at the surface of phosphosilicate glass particle, wherein curve A corresponds to a phosphosilicate glass of the formula 85SiO₂-15P₂O₅ and curve B corresponds to a phosphosilicate glass of the formula 50SiO₂-50P₂O₅;

FIG. 3 is a schematic diagram showing an embodiment of a method of selectively removing phosphorus from a surface of an inorganic particle;

FIG. 4 is a cross-sectional view of an embodiment of a solar cell;

FIG. 5 is a cross-sectional view of another embodiment of a solar cell; and

FIG. 6 is a cross-sectional view of another embodiment of a solar cell.

### DETAILED DESCRIPTION

This disclosure will be described more fully hereinafter with reference to the accompanying drawings, in which exemplary embodiments are shown. This disclosure may, however, be embodied in many different forms and should not be construed as limited to the exemplary embodiments set forth herein.

As used herein, the term “and/or” includes any and all combinations of one or more of the associated listed items.

It will be understood that, although the terms “first,” “second,” “third” etc. may be used herein to describe various elements, components, regions, layers, and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

First, a doping paste according to an embodiment will be further described.

A doping paste according to an embodiment comprises an inorganic particle comprising a phosphorus-containing silicon compound and an organic vehicle.

The phosphorus-containing silicon compound may include, for example, a phosphosilicate, such as a phosphosilicate crystal, a phosphosilicate glass, or a combination thereof.

The phosphorus-containing silicon compound may be, for example, a phosphosilicate glass represented by the following Chemical Formula 1.

xSiO₂-yP₂O₅-zMO₁ Chemical Formula 1

In Chemical Formula 1, x>0, y>0, z≧0, M is a metal, and x, y, and z are the amount of SiO₂, P₂O₅, and MO₁, respectively, in mole percent (mol %). In another embodiment, x>0.1, y>0.1, and z≧0, specifically x>0.2, y>0.2, and z≧0, more specifically x>40, y>1, and z≧0. In another embodiment, x>0.1, y>0.1, and z>0, specifically x>0.2, y>0.2, and z>0, more specifically x>40, y>1, and z>0.

M, if present, may be a metal of Groups 1 to 14, specifically Groups 3 to 13, more specifically Groups 4 to 13, or Groups 5 to 12 of the Periodic Table of the Elements.

A concentration of phosphorus at an interior portion of the inorganic particle may be greater than a concentration of phosphorous at a surface of the inorganic particle. Thus the concentration of phosphorous may decrease in a direction from a center of the inorganic particle to provide a concentration gradient. The concentration gradient may be provided by selectively removing phosphorous from a surface of the inorganic particle.

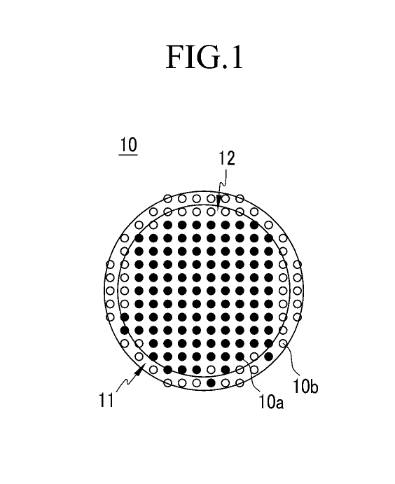

This will be further explained referring to FIG. 1.

FIG. 1 is a schematic diagram showing an inorganic particle of a doping paste according to an embodiment.

Referring to FIG. 1, an inorganic particle 10 comprises a phosphorus-containing silicon compound to which phosphorus (P) 10a, silicon (Si) 10b, and oxygen (O) (not shown) are chemically bound.

In an embodiment, a concentration of phosphorus at an interior portion of the inorganic particle 10 is greater than a concentration of phosphorous at a surface of the inorganic particle.

In an embodiment, the inorganic particle 10 comprises a phosphorus-rich region 12 located at the center and a silicon-rich region 11 located at the surface of the inorganic particle. Specifically, as explained above, at the surface of the inorganic particle 10, phosphorus 10a may be selectively removed to provide the silicon-rich region 11, and thus the silicon-rich region 11 has a relatively lower ratio of phosphorus to silicon than the phosphorus-rich region 12.

Thus, by removing phosphorus at the surface of the inorganic particle 10, reaction of phosphorus, which may be present at the surface of the inorganic particle 10, with carbon (C) of an organic substance may be substantially reduced or effectively eliminated, wherein such a reaction may occur during a synthesis of the inorganic particle or during the manufacture, processing, or use of a doping paste comprising the inorganic particle.

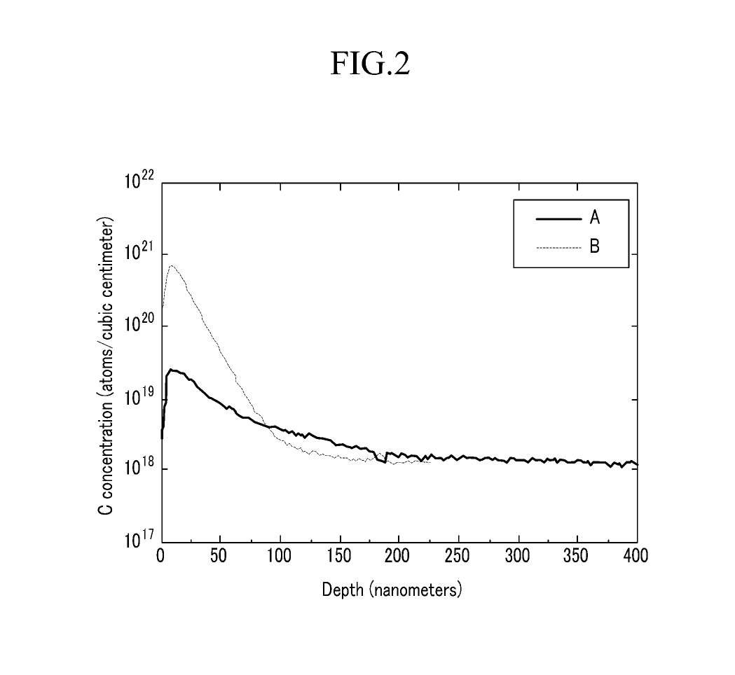

This will be further explained referring to FIG. 2.

FIG. 2 is a secondary ion mass spectrometry (“SIMS”) graph showing the content of adsorbed carbon (C) according to the content of phosphorus existing at the surface of a phosphosilicate glass particle.

FIG. 2 shows that if the phosphorus content at the phosphosilicate glass particle surface is 50 arbitrary units (“arb.unit %”) (curve B in FIG. 2, corresponding to 50SiO₂-50P₂O₅), the content of carbon (C) adsorbed at the surface is greater than when the phosphorous content is 15 arb.unit % (curve A in FIG. 2, corresponding to 85SiO₂-15P₂O₅). Thus, the results of FIG. 2 show that as the content of phosphorus present at the particle surface increases, the adsorbed carbon (C) content also increases.

If an inorganic particle includes a large amount of adsorbed carbon, when a doping paste including the inorganic particle is applied to a solar cell, carbon is adsorbed in a semiconductor layer and can function as a recombination center, promoting recombination of electrons and holes, thus deteriorating solar cell efficiency.

According to an embodiment, by providing a particle wherein the silicon-region at the surface of the particle has a ratio of phosphorous to silicon which is less than a ratio of phosphorous to silicon at an interior portion of the particle, for example by removing phosphorus located at the surface of a particle comprising the phosphorus-containing silicon compound (of the inorganic particle) of the doping paste, bonding of carbon included in an organic material to the inorganic particle surface during the synthesis of the inorganic particle or during the manufacture of the doping paste may be substantially prevented or effectively reduced. Thus, when an emitter layer of a solar cell is formed using the doping paste, adsorption of carbon in a semiconductor substrate may be substantially prevented or effectively reduced, thus reducing recombination of electrons and holes to prevent deterioration of solar cell efficiency.

The phosphorous concentration at the surface may be provided by selective removal of phosphorus at the surface of the inorganic particle by various methods.

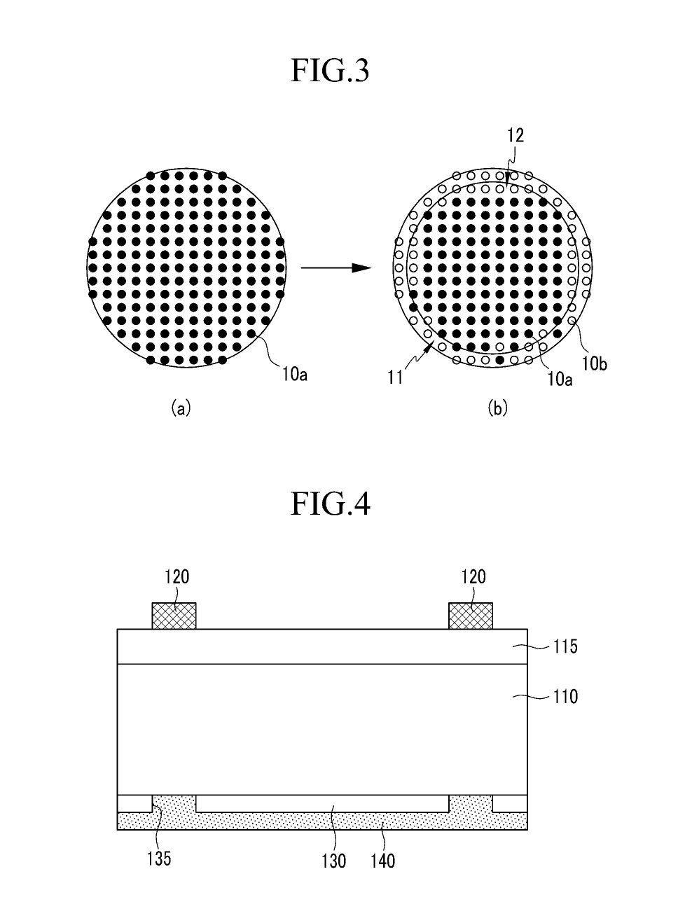

An example will be further explained referring to FIG. 3.

FIG. 3 is a schematic diagram showing an embodiment of a method of selectively removing phosphorus from the surface of an inorganic particle.

First, a phosphorus-containing silicon compound, such as phosphosilicate glass is prepared (a). The phosphorus-containing silicon compound includes uniformly distributed phosphorus 10a and silicon (not shown) throughout the particle.

Subsequently, the inorganic particle comprising the phosphorus-containing silicon compound is contacted with liquid, vapor, or supercritical water at a high pressure, e.g., about 0.1 to about 20 megaPascals (MPa), specifically about 1 to about 15 MPa, more specifically about 10 MPa. Subsequently, the inorganic particle is contacted with water or an organic solvent to clean the inorganic particle.

Thereby, phosphorus may be eluted from the surface of the inorganic particle to form a phosphorus-rich region 12 located at the center of the inorganic particle and a silicon-rich region 11 located at the surface of the inorganic particle, wherein the silicon-rich region 11 has a relatively lower ratio of phosphorus to silicon than the phosphorus-rich region, as shown in FIG. 3 (b). A concentration of phosphorous at the surface of the particle may be about 1 to about 99 percent (%), specifically about 5 to about 95%, more specifically about 10 to about 90% of the concentration of phosphorous at an interior portion of the particle.

For example, an inorganic particle is prepared and removal of phosphorus is confirmed by the following method.

In an autoclave, about 200 milliliters (mL) of thrice distilled water is introduced and 1 gram (g) of phosphosilicate powder is added. Subsequently, elution amounts of phosphorus and silicon ions according to time are measured, and the results described in the following Table 1 are obtained.

TABLE 1

| Reaction time | | Phosphorus (P) ion (ppm) | Silicon (Si) ion (ppm) |
|---|---|---|---|
| 10 | minutes | 61.65 | 6.96 |
| 30 | minutes | 121.22 | 14.54 |
| 1 | hour | 161.33 | 19.54 |
| 2.5 | hours | 281.37 | 13.92 |
| 3 | hours | 302.43 | 12.24 |
| 4 | hours | 364.78 | 6.97 |

ppm refers to parts per million.

Referring to Table 1, and while not wanting to be bound by theory, when an inorganic particle including a phosphorus-containing silicon compound is contacted with water, over time the eluted concentration of silicon (Si) ion is small, and the eluted concentration of phosphorus is relatively high. Thus, it may be seen that a large amount of phosphorus may be eluted from the inorganic particle surface and thus removed by the above method.

The inorganic particle may have a particle size of about 0.5 to about 50 micrometers (μm), specifically about 1 to about 40 μm, more specifically about 2 to about 30 μm.

The organic vehicle may include an organic, an optional organic solvent, and optional additives known for use in the manufacture of conductive pastes for solar cells. The organic vehicle is combined with the conductive powder and the metallic glass primarily to provide a viscosity rheology to the conductive paste effective for printing or coating the conductive. A wide variety of inert organic materials can be used, and can be selected by one of ordinary skill in the art without undue experimentation to achieve the desired viscosity and rheology, as well as other properties such as dispersibility of the conductive powder and the metallic glass, stability of conductive powder and the metallic glass and any dispersion thereof, drying rate, firing properties, and the like. Similarly, the relative amounts of the organic compound, any optional organic solvent, and any optional additive can be adjusted by one of ordinary skill in the art without undue experimentation in order to achieve the desired properties of the conductive paste.

The organic compound may be, for example, a polymer such as a C1 to C4 alkyl (meth)acrylate-based resin; a cellulose such as ethyl cellulose or hydroxyethyl cellulose; a phenol resin; a wood rosin; an alcohol resin; a halogenated polyolefin such as tetrafluoroethylene (e.g., TEFLON); the monobutyl ether of ethylene glycol monoacetate, or the like, or a combination thereof.

The solvent may be any solvent which can dissolve or suspend the organic compound, and it may, for example, terpineol, butylcarbitol, butylcarbitol acetate, pentanediol, dipentene, limonene, an ethylene glycol alkylether, a diethylene glycol alkylether, an ethylene glycol alkylether acetate, a diethylene glycol alkylether acetate, a diethylene glycol dialkylether acetate, a triethylene glycol alkylether acetate, a triethylene glycol alkylether, a propylene glycol alkylether, propylene glycol phenylether, a dipropylene glycol alkylether, a tripropylene glycol alkylether, a propylene glycol alkylether acetate, a dipropylene glycol alkylether acetate, a tripropylene glycol alkylether acetate, dimethylphthalic acid, diethylphthalic acid, dibutylphthalic acid, deionized water, or a combination thereof.

The inorganic particle and the organic vehicle may be included in an amount of about 1 to about 80 weight percent (wt %) and about 20 to about 99 wt %, specifically about 2 to about 70 wt % and about 30 to about 98 wt %, more specifically about 4 to about 60 wt % and about 40 to about 96 wt %, respectively, based on the total weight of the doping paste.

Because the doping paste includes the phosphorus-containing silicon compound, it includes an n-type phosphorus dopant, and thus it may be applied as an n+ emitter layer of a solar cell.

Hereinafter, an embodiment of a solar cell including a product of the above-disclosed doping paste will be further described referring to FIG. 4.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, for the better understanding and ease of description, upper and lower positional or spatial relationships are described with respect to a semiconductor substrate 110, but is not limited thereto. In addition, “front side” refers to the side receiving solar energy and “rear side” refers to the side opposite to the front side hereinafter.

FIG. 4 is a cross-sectional view of an embodiment of a solar cell.

The solar cell according to an embodiment includes a semiconductor substrate 110, an emitter layer 115, a front electrode 120, a dielectric layer 130, and a rear electrode 140.

The semiconductor substrate 110 may be, for example, a silicon wafer, and it may be doped with, for example, a p-type impurity. The p-type impurity may be a Group III compound such as boron (B).

The semiconductor substrate 110 may have a textured surface. The semiconductor substrate 110 with the textured surface may have protrusions and depressions, and may comprise a pyramidal shape, or may have a porous structure having a honeycomb shape, for example. The semiconductor 110 with the textured surface may effectively increase the amount of light absorbed into a solar cell by increasing light scattering, and thereby lengthening a light transfer path while reducing reflectance of incident light.

The emitter layer 115 may be an n-layer formed using the above described doping paste. As further disclosed above, the doping paste may include an inorganic particle including a phosphorus-containing silicon compound wherein a concentration of phosphorus at an interior portion of the inorganic particle is greater than a concentration of phosphorous at a surface of the inorganic particle. The concentration gradient of phosphorous may be provided by selectively removing phosphorous from the surface of the inorganic particle. The doping paste may further comprise an organic vehicle, and the doping paste may be applied on the textured surface of the semiconductor substrate 110 by screen printing, for example.

A front electrode 120 may be disposed (e.g., formed) on a surface of the emitter layer 115. The front electrode 120 may extend along a direction of the substrate in parallel to a direction of the substrate, and may have a grid pattern shape to reduce a shadowing loss and/or a sheet resistance.

The front electrode 120 may comprise a conductive material, for example a low resistivity metal such as silver (Ag). The front electrode 120 may be disposed (e.g., formed) using the conductive paste including a conductive material.

A front electrode bus bar (not shown) may be disposed on the front electrode 120. The front electrode bus bar can connect adjacent solar cells when a plurality of solar cells are assembled.

A dielectric layer (not shown) may be disposed (e.g., formed) on the lower side of the semiconductor substrate 110. The dielectric layer 130 may prevent recombination of electric charges and simultaneously prevent current leakage, thereby increasing solar cell efficiency. The dielectric layer 130 may have a through-hole 135, and the semiconductor substrate 110 and the rear electrode 140, which are described below, may contact each other through the through-hole 135.

The dielectric layer 130 may comprise, for example, silicon oxide (SiO₂), silicon nitride (SiNₓ), aluminum oxide (Al₂O₃), or a combination thereof, and it may have a thickness of about 100 to about 2000 angstroms (Å), specifically about 200 to about 1800 Å, more specifically about 300 to about 1600 Å.

The rear electrode 140 is disposed (e.g., formed) on the lower side of the dielectric layer 130. The rear electrode 140 may comprise a conductive material, for example an opaque material such as aluminum (Al). The rear electrode 140 may be formed by screen printing a conductive paste in the same manner as the front electrode 120.

Hereinafter, a method of manufacturing the solar cell will be disclosed referring to FIG. 4.

First, a doping paste for an emitter layer is prepared.

The doping paste includes an inorganic particle including a phosphorus-containing silicon compound, and an organic vehicle, wherein a concentration of phosphorus at an interior portion of the inorganic particle is greater than a concentration of phosphorous at a surface of the inorganic particle, as described above. The concentration of phosphorous at the surface of the particle may be provided by selectively removing phosphorous from the surface of the inorganic particle, as disclosed above.

The selective removal of phosphorus at the surface of the inorganic particle may be performed by contacting the phosphorus-containing silicon compound with water in the form of a liquid, vapor, or supercritical fluid, and then cleaning the phosphorus-containing silicon compound in water or an organic solvent.

Then, a semiconductor substrate 110, such as a silicon wafer, is prepared. The semiconductor substrate 110 may be doped with a p-type impurity.

Subsequently, the semiconductor substrate 110 is surface-textured. The surface texturing may be performed by a wet method using a strong acid such as nitric acid, hydrofluoric acid, or the like, or a combination thereof, or a strong base such as sodium hydroxide, or the surface texturing may be performed by a dry method such as plasma treatment.

Then, on the front side of the semiconductor substrate 110, the doping paste is applied. The doping paste may be applied by, for example, screen printing.

Subsequently, the semiconductor substrate 110 to which the doping paste is applied is subjected to heat treatment. The heat treatment may be performed in two steps. First, a first heat treatment is performed at a relatively low temperature to remove an organic vehicle included in the doping paste, and then a second heat treatment is performed at a temperature which is higher than the first heat treatment to dope the semiconductor substrate. The first heat treatment may be performed at, for example, about 100° C. to about 600° C., specifically about 150° C. to about 550° C., more specifically about 200° C. to about 500° C., and the second heat treatment may be performed at about 700° C. to about 1100° C., specifically about 650° C. to about 1000° C. more specifically about 600° C. to about 900° C. Thereby, on the front side of the semiconductor substrate 110, an emitter layer 115 may be formed.

Then, on the upper side of the emitter layer 115, a conductive paste for a front electrode is applied. The conductive paste for a front electrode may be applied by, for example, screen printing.

Subsequently, the conductive paste for a front electrode is dried.

Then, on the rear side of the semiconductor substrate 110, aluminum oxide (Al₂O₃) or silicon oxide (SiO₂), for example, are disposed (e.g., deposited) by plasma enhanced chemical vapor deposition (“PECVD”), for example, to form a dielectric layer 130.

Subsequently, a laser is radiated onto a portion of the dielectric layer 130 to form a through-hole 135.

Then, on a side of the dielectric layer 130, a conductive paste for a rear electrode is applied by screen printing and dried.

Subsequently, the conductive paste for a front electrode and the conductive paste for a rear electrode are co-fired (e.g., heat treated), or fired individually. However, the conductive paste for a front electrode and the conductive paste for a rear electrode may be separately fired, without limitations. Thus the conductive paste of the front electrode and the conductive paste of the rear electrode may be fired in the same or in different processes.

The temperature of the firing furnace may be elevated to a temperature which is higher than the fusion temperature of the conductive metal, and the firing may be performed at, for example, about 400° C. to about 1000° C., specifically about 450° C. to about 900° C., more specifically about 500° C. to about 800° C.

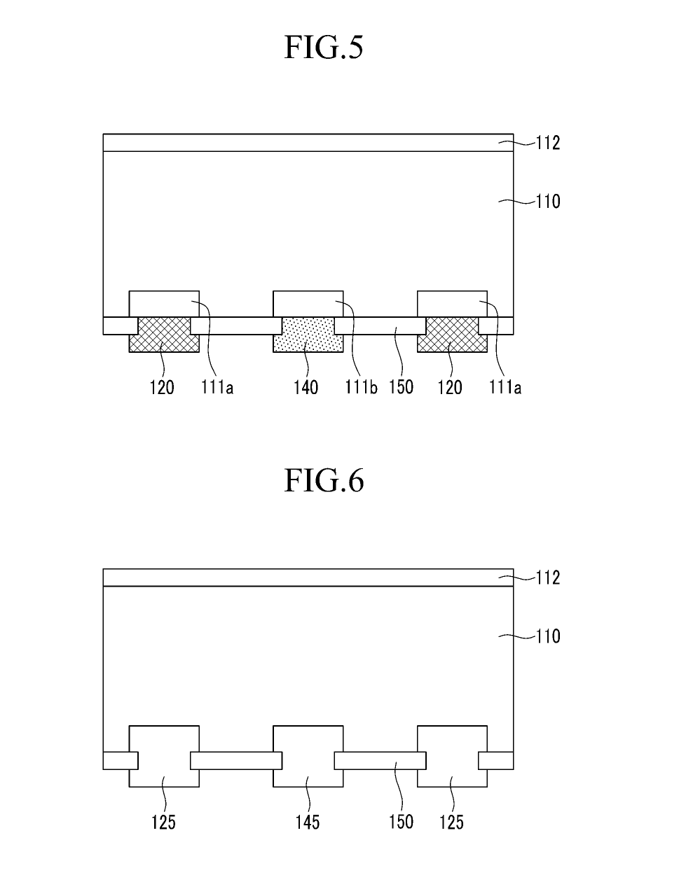

Hereinafter, a solar cell according to another embodiment will be described referring to FIG. 5.

FIG. 5 is a cross-sectional view of an embodiment of a solar cell according to another embodiment.

The solar cell according to this embodiment includes a semiconductor substrate 110 doped with a p-type or n-type impurity.

On the rear side of the semiconductor substrate 110, a first doping region 111a and a second doping region 111b that are doped with different impurities are formed.

The first doping region 111a may be doped with, for example, an n-type impurity, and the second doping region 111b may be doped with, for example, a p-type impurity. The first doping region 111a and the second doping region 111b may be alternatively disposed on the rear side of the semiconductor substrate 110.

The first doping region 111a may be formed using the above-explained doping paste which includes a phosphorus-containing silicon compound, and the first doping region 111a may correspond to the emitter layer 115 of the above-explained embodiment.

The second doping region 111b may be formed using a p-type doping paste.

The front side of the semiconductor substrate 110 may have a textured surface, and the surface texturing may increase light absorption and decrease reflectance of incident light to improve solar cell efficiency. On the front side of the semiconductor substrate 110, an insulation layer 112 may be disposed (e.g., formed). The insulation layer 112 may comprise a material that is substantially transparent, and thus absorbs less light, and provides insulating properties. The insulation layer 112 may comprise, for example silicon nitride (SiNₓ), silicon oxide (SiO₂), titanium oxide (TiO₂), aluminum oxide (Al₂O₃), magnesium oxide (MgO), or cerium oxide (CeO₂), or a combination thereof, and it may be disposed (e.g., formed) as a single layer or as multiple layers. The insulation layer 112 may have a thickness of, for example, about 200 to about 1500 Å, specifically 300 to about 1400 Å, more specifically about 400 to about 1300 Å.

The insulation layer 112 may function as an anti-reflective coating that reduces reflectance of light at the solar cell surface and increases selectivity to a specific wavelength region, and simultaneously, it may improve contact properties with silicon at the surface of the semiconductor substrate 110 to increase solar cell efficiency.

On the rear side of the semiconductor substrate 110, a dielectric layer 150 having a through-hole is disposed (e.g., formed).

On the rear side of the semiconductor substrate 110, a front electrode 120 electrically connected to the first doping region 111a, and a rear electrode 140 electrically connected to the second doping region 111b are respectively disposed (e.g., formed). The front electrode 120 may contact the first doping region 111a through the through-hole, and the rear electrode 140 may contact the second doping region 111b through the through-hole. The front electrode 120 and the rear electrode 140 may be alternatively disposed.

The front electrode 120 and the rear electrode 140 may be formed using a conductive paste including a conductive material.

According to this embodiment, differently from the above-explained embodiment, both the front electrode 120 and the rear electrode 140 are located on the rear side of the solar cell, thus an area occupied by electrodes (e.g., metal) at the front surface is reduced, reducing shadowing loss, thereby increasing solar cell efficiency.

Hereinafter, a method of manufacturing a solar cell according to this embodiment will be explained with reference to FIG. 5.

First, a semiconductor substrate 110 doped with n-type or p-type impurity is prepared. Subsequently, the surface of the semiconductor substrate 110 is textured, and then, on the front side and rear side of the semiconductor substrate 110, insulation layer 112 and dielectric layer 150 are respectively formed. The insulation layer 112 and the dielectric layer 150 may be formed by, for example, chemical vapor deposition (“CVD”), for example.

Subsequently, on the rear side of the semiconductor substrate 110, the above-disclosed doping paste, which comprises an inorganic particle comprising the phosphorus-containing silicon compound and an organic vehicle, is applied to a portion of the rear side of the semiconductor substrate 110. Heat treatment is then performed to remove the organic vehicle of the doping paste and dope the semiconductor substrate with an n-type impurity to form the first doping region 111a. Two steps of heat treatment may be performed as described in the above embodiment.

Subsequently, on the rear side of the semiconductor substrate 110, a p-type doping paste is applied to a portion of the rear side of the semiconductor substrate 110. The p-type doping paste may be disposed between adjacent first doping regions 111a. Subsequently, heat treatment is performed to remove the organic vehicle in the p-type doping paste and dope the semiconductor substrate with the p-type impurity to form the second doping region 111b.

Subsequently, on a side of the dielectric layer 150, a conductive paste for a front electrode is applied on the region corresponding to the first doping region 111a, and a conductive paste for a rear electrode is applied on the region corresponding to the second doping region 111b. The conductive paste for the front electrode and the conductive paste for the rear electrode may be disposed by screen printing, for example.

Subsequently, the conductive paste for the front electrode and the conductive paste for the rear electrode may be simultaneously or individually fired, and the temperature of the firing furnace may be elevated to a temperature higher than the fusion temperature of the conductive metal.

Hereinafter, a solar cell according to yet another embodiment will be described with reference to FIG. 6.

FIG. 6 is a cross-sectional view of yet another embodiment of a solar cell.

The solar cell according to this embodiment, similarly to the above-explained embodiment, includes a semiconductor substrate 110 doped with a p-type or n-type impurity, an insulation layer 112 disposed on the front side of the semiconductor substrate 110 and a dielectric layer 150 disposed on the rear side of the semiconductor substrate 110.

However, according to this embodiment, unlike the above-explained embodiment, on the rear side of the semiconductor substrate 110, a first doping region including an n-type impurity and an electrode including a conductive material are integrated to provide an integrated n-type doping region-electrode 125. Also a second doping region including a p-type impurity and an electrode including a conductive material are integrated to provide an integrated p-type doping region electrode 145.

Thus, a single conductive paste is used as the doping paste for a doping region and the doping paste for an electrode to integrate the doping region and the electrode. Specifically, on the rear side of the semiconductor substrate 110, a conductive paste that includes an inorganic material comprising the phosphorus-containing silicon compound, a conductive material for an electrode, and an organic vehicle is applied to a portion of the semiconductor substrate 110 to form an integrated n-type doping region-electrode 125, and on the rear side of the semiconductor substrate 110, a conductive paste that comprises a p-type dopant material, a conductive material for an electrode, and an organic vehicle is applied on the portion of the semiconductor substrate 110 where the integrated n-type doping region-electrode 125 is not disposed to form an integrated p-type doping region-electrode 145.

According to this embodiment, the process may be simplified by simultaneously forming a doping region and an electrode using a paste.

Although the solar cell is explained as an example, the utility of the paste is not limited to the forming of an electrode for a solar cell and may be applied to provide an electrode in other electronic devices, such as a plasma display panel (“PDP”), a liquid crystal display (“LCD”), or an organic light emitting diode (“OLED”).

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A doping paste comprising in combination:
an inorganic particle comprising a phosphorus-containing silicon compound, and
an organic vehicle,
wherein a concentration of phosphorus at an interior portion of the inorganic particle is greater than a concentration of phosphorous at a surface of the inorganic particle.

2. The doping paste of claim 1, wherein the concentration of phosphorous decreases in a direction from a center of the inorganic particle.

3. The doping paste of claim 1, wherein the phosphorus-containing silicon compound comprises a phosphosilicate crystal, a phosphosilicate glass, or a combination thereof.

4. The doping paste of claim 1, wherein the phosphorus-containing silicon compound comprises a phosphosilicate glass represented by the following Chemical Formula 1:
xSiO₂-yP₂O₅-zMO₁ Chemical Formula 1
wherein, in Chemical Formula 1, x>0, y>0, z≧0, and M is a metal.

5. The doping paste of claim 1, wherein the inorganic particle comprises
a phosphorus-rich region located at a center of the inorganic particle, and
a silicon-rich region located at the surface of the inorganic particle, and
wherein the silicon-rich region has a ratio of phosphorus to silicon which is less than a ratio of phosphorous to silicon of the phosphorus-rich region.

6. The doping paste of claim 1, wherein the inorganic particle has particle size of about 0.5 to about 50 micrometers.

7. The doping paste of claim 1, wherein the inorganic particle and the organic vehicle are present in an amount of about 1 to about 80 weight percent and about 20 to about 99 weight percent, respectively, based on a total weight of the doping paste.

8. A method of manufacturing a solar cell, comprising:
disposing an n-type doping paste comprising an inorganic particle and an organic vehicle on a first surface of a semiconductor substrate, wherein the inorganic particle comprises a phosphorus-containing silicon compound and an organic vehicle, and wherein a concentration of phosphorus at an interior portion of the inorganic particle is greater than a concentration of phosphorous at a surface of the inorganic particle; and
heat-treating the semiconductor substrate onto which the n-type doping paste is disposed.

9. The method of claim 8, further comprising preparing the inorganic particle, wherein the preparing of the inorganic particle comprises:
contacting a particle comprising the phosphorus-containing silicon compound with water to remove phosphorous from the surface of the inorganic particle, wherein the water is a liquid, a vapor, or a supercritical fluid; and then
contacting the particle comprising the phosphorus-containing silicon compound with water or an organic solvent to clean the particle.

10. The method of claim 8, wherein the disposing comprises
disposing the n-type doping paste on an entire surface of or a portion of a surface of the semiconductor substrate by screen printing.

11. The method of claim 8, wherein the heat-treating of the semiconductor substrate onto which the n-type doping paste is disposed comprises:
heat-treating at a first temperature to remove the organic vehicle; and then
heat-treating at a second temperature, which is higher than the first temperature, to dope the semiconductor substrate with an n-type impurity.

12. The method of claim 11, wherein the first temperature is about 100° C. to about 600° C.

13. The method of claim 11, wherein the second temperature is about 700° C. to about 1100° C.

14. The method of claim 8, further comprising after the heat-treating of the semiconductor substrate:
disposing a p-type doping paste, which is different than the n-type doping paste, on a second surface of the semiconductor substrate, and then
heat-treating the semiconductor substrate.

15. The method of claim 14, wherein the n-type doping paste and the p-type doping paste are disposed on a same side of the semiconductor substrate, and
the n-type doping paste and the p-type doping paste are alternately disposed.

16. A solar cell comprising:
a semiconductor substrate;
an emitter layer disposed on a side of the semiconductor substrate; and
an electrode electrically connected with the emitter layer,
wherein the emitter layer comprises a heat-treated product of a doping paste which comprises an inorganic particle including a phosphorus-containing silicon compound, wherein a concentration of phosphorus at an interior portion of the inorganic particle is greater than a concentration of phosphorous at a surface of the inorganic particle.

17. The solar cell of claim 16, wherein the phosphorus-containing silicon compound comprises a phosphosilicate glass represented by the following Chemical Formula 1:
xSiO₂-yP₂O₅-zMO₁ Chemical Formula 1
wherein, in Chemical Formula 1, x>0, y>0, z≧0, and M is a metal.

18. The solar cell of claim 16, wherein the inorganic particle comprises:
a phosphorus-rich region located at a center of the inorganic particle; and
a silicon-rich region located at the surface of the inorganic particle, and
wherein the silicon-rich region has a ratio of phosphorus to silicon which is less than a ratio of phosphorous to silicon of the phosphorus-rich region.

19. The solar cell of claim 16, wherein the emitter layer is disposed on an entire surface or on a portion of a surface of the semiconductor substrate.

20. The solar cell of claim 16, wherein the doping paste further comprises a conductive material, and
the emitter layer and the electrode are integratedly formed using the doping paste.

21. An electronic device comprising:
an electrode comprising a heat-treated product of the doping paste according to claim 1.
